(19) United States
(12) Patent Application Publication
(10) Pub. No.: US 2026/0173741 A1
(43) Pub. Date: Jun. 18, 2026

(54) Pixel Arrangement Structure, Display Panel and Display Device

(71) Applicant: BOE Technology Group Co., Ltd., Beijing (CN)

(72) Inventors: Wenxiu ZHU, Beijing (CN); Song ZHANG, Beijing (CN)

(21) Appl. No.: 18/712,720

(22) PCT Filed: May 11, 2023
(86) PCT No.: PCT/CN2023/093627

§ 371 Date: May 23, 2024

(51) Int. Cl. H10K 59/80; H10K 59/121

(52) U.S. Cl. CPC H10K 59/8792; H10K 59/121

(57) ABSTRACT

A pixel arrangement structure, a display panel and a display device are provided. The pixel arrangement structure (18) includes a plurality of conventional display areas (S1) and a plurality of anti-peep display areas (S2). The plurality of conventional display areas (S1) and the plurality of anti-peep display areas (S2) are provided to be controlled to be lit up and turned off individually, and all extend in a first direction. The plurality of conventional display areas (S1) and the plurality of anti-peep display areas (S2) are alternately arranged in a second direction. The first direction intersects with the second direction. The display panel includes the pixel arrangement structure (18) described above. The display device includes the display panel described above.

### CROSS-REFERENCE TO RELATED APPLICATION

The present application is a U.S. National Phase Entry of International Application No. PCT/CN2023/093627 having an international filing date of May 11, 2023. Contents of the above-identified application are incorporated into the present application by reference.

### TECHNICAL FIELD

The present disclosure relates to, but is not limited to, the display technical field, and in particular to a pixel arrangement structure, a display panel and a display device.

### BACKGROUND

An active matrix organic light emitting diode (AMOLED) display screen needs anti-peep function in some private scenes, that is, anti-peep state, but it needs to share screen information in some public scenes, that is, sharing state, which requires AMOLED display screen to have an anti-peep state and a sharing state, and have the function of switching states at any time. For example, when a user is viewing information on a mobile phone display screen in public, especially when presenting the payment code or entering the password, the display screen may be switched to the anti-peep state, and in other cases, it may be switched to the sharing state. In addition, such as for the on-board application display screen, when the co-pilot watches entertainment information, the display screen may be switched to the anti-peep state, and in other cases, it may be switched to the sharing state.

The current display panel cannot directly switch between the anti-peep state and the sharing state, or the display effect is poor in the anti-peep state or the sharing state.

### SUMMARY

The following is a summary of subject matters described herein in detail. This summary is not intended to limit the protection scope of the claims.

At least one embodiment of the present disclosure provides a pixel arrangement structure, including a plurality of conventional display areas and a plurality of anti-peep display areas. The plurality of conventional display areas and the plurality of anti-peep display areas are provided to be controlled to be lit up and turned off individually, and all extend in a first direction. The plurality of conventional display areas and the plurality of anti-peep display areas are alternately arranged in a second direction. The first direction intersects with the second direction.

In some exemplary embodiments, a conventional display area includes a plurality of first repeating units sequentially arranged in the first direction, and an anti-peep display area includes a plurality of second repeating units sequentially arranged in the first direction.

The first repeating units in the plurality of conventional display areas and the second repeating units in the plurality of anti-peep display areas are arranged in an array.

In some exemplary embodiments, the second repeating units and the first repeating units are arranged alternately in the second direction.

A first repeating unit includes a plurality of conventional sub-pixels, and a second repeating unit includes a plurality of anti-peep pixel groups.

In adjacent first repeating unit and second repeating unit, at least one of the conventional sub-pixels in the first repeating unit is provided corresponding to at least one of the anti-peep pixel groups in the second repeating unit and has a same color as at least one of the anti-peep pixel groups in the second repeating unit.

In some exemplary embodiments, part of the conventional sub-pixels in the first repeating unit is provided corresponding to part of the anti-peep pixel groups in an adjacent second repeating unit and has a same color as part of the anti-peep pixel groups in an adjacent second repeating unit, and the other part of the conventional sub-pixels is provided corresponding to part of the anti-peep pixel groups in another second repeating unit and has a same color as part of the anti-peep pixel groups in another second repeating unit.

In some exemplary embodiments, the plurality of conventional sub-pixels include a first conventional sub-pixel, a second conventional sub-pixel, and a third conventional sub-pixel, and the plurality of anti-peep pixel groups include a first anti-peep pixel group, a second anti-peep pixel group, and a third anti-peep pixel group.

The first anti-peep pixel group is provided to be consistent in color with the second conventional sub-pixel, the second anti-peep pixel group is provided to be consistent in color with the first conventional sub-pixel, and the third anti-peep pixel group is provided to be consistent in color with the third conventional sub-pixel.

In some exemplary embodiments, at least one of the anti-peep pixel groups includes a plurality of anti-peep sub-pixels, and the plurality of anti-peep sub-pixels are provided at pairwise intervals.

In some exemplary embodiments, at least one of the anti-peep pixel groups includes two anti-peep sub-pixels, and the two anti-peep sub-pixels are provided at intervals in the first direction.

In some exemplary embodiments, an outer contour of at least one of the conventional sub-pixels is provided as a first rectangle, long sides of the first rectangle extends in the first direction, and outer contours of two of the anti-peep sub-pixels are provided as identical second rectangles.

In some exemplary embodiments, an outer contour of at least one of the conventional sub-pixels is provided as a first triangle, and outer contours of two of the anti-peep sub-pixels are provided as two second triangles of the same size.

In some exemplary embodiments, all the first triangle and the second triangles are provided as right triangles, and a hypotenuse of the first triangle is provided to face an adjacent anti-peep pixel group.

Hypotenuses of the two second triangles are provided facing away from each other, and a right-angled side of a second triangle is provided to face an adjacent conventional sub-pixel.

At least one embodiment of the present disclosure provides a display panel, including a substrate, a pixel definition layer and a light shielding structure, and further including the pixel arrangement structure described above. The pixel definition layer is provided on the substrate, and is provided with an opening area. The pixel arrangement structure is provided corresponding to the opening area. The light shielding structure is provided on a side of the pixel definition layer facing away from the substrate.

At least one embodiment of the present disclosure provides a display panel, including a substrate, a pixel definition layer, a light shielding structure and a light control film, and further including the pixel arrangement structure described above. The pixel definition layer is provided on the substrate, and is provided with an opening area. The pixel arrangement structure is provided corresponding to the opening area. The light shielding structure is located on a side of the pixel definition layer facing away from the substrate.

The light control film is provided to extend from the pixel definition layer to a side of the light shielding structure facing away from the pixel definition layer.

In some exemplary embodiments, the light shielding structure includes a first black matrix layer spaced apart from the pixel definition layer and a second black matrix layer provided on a side of the first black matrix layer facing away from the pixel definition layer. A distance between the first black matrix layer and the second black matrix layer is greater than 0.

The light control film is provided to extend from the pixel definition layer to the second black matrix layer, and the light control film is provided between two adjacent anti-peep sub-pixels.

At least one embodiment of the present disclosure provides a display device including the display panel described above.

Other aspects of the present disclosure may be comprehended after the drawings and the detailed descriptions are read and understood.

### BRIEF DESCRIPTION OF DRAWINGS

FIG. 1 is a schematic diagram of a pixel arrangement structure according to an embodiment of the present disclosure;

FIG. 2 is a partial schematic diagram of the pixel arrangement structure in FIG. 1;

FIG. 3 is a schematic diagram of a first repeating unit in FIG. 2;

FIG. 4 is a schematic diagram of a second repeating unit in FIG. 2;

FIG. 5 is a schematic diagram of a pixel arrangement structure according to another embodiment of the present disclosure;

FIG. 6 is a schematic diagram of a pixel arrangement structure according to yet another embodiment of the present disclosure;

FIG. 7 is a schematic diagram of a pixel arrangement structure according to further another embodiment of the present disclosure;

FIG. 8 is a schematic diagram of a pixel arrangement structure according to yet another embodiment of the present disclosure;

FIG. 9 is a schematic diagram of a pixel arrangement structure according to further another embodiment of the present disclosure;

FIG. 10 is a partial schematic diagram of the pixel arrangement structure in FIG. 9;

FIG. 11 is a schematic diagram of a first repeating unit in FIG. 10;

FIG. 12 is a schematic diagram of a second repeating unit in FIG. 10;

FIG. 13 is a schematic diagram of a pixel arrangement structure according to yet another embodiment of the present disclosure;

FIG. 14 is a schematic diagram of a display panel according to an embodiment of the present disclosure;

FIG. 15 is a schematic diagram of light of the display panel in FIG. 14 in a display state;

FIG. 16 is a schematic diagram of light of the display panel in FIG. 14 in an anti-peep state;

FIG. 17 is a schematic diagram of a first black matrix layer in FIG. 14;

FIG. 18 is a schematic diagram of a second black matrix layer in FIG. 14; and

FIG. 19 is a schematic diagram of a display panel according to yet another embodiment of the present disclosure.

### DETAILED DESCRIPTION

Embodiments of the present disclosure will be described in detail hereinafter with reference to the drawings. It is to be noted that the embodiments and features in the embodiments of the present disclosure may be randomly combined with each other if there is no conflict.

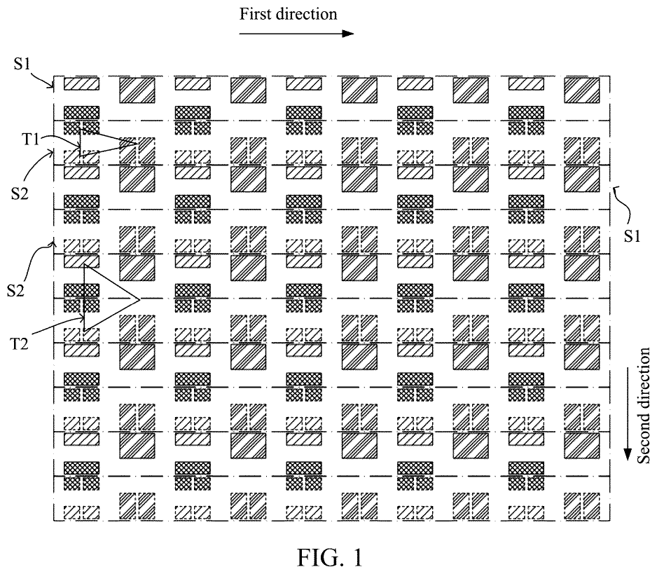

Referring to a pixel arrangement structure of an embodiment of the present disclosure of FIGS. 1 to 12, the pixel arrangement structure includes a plurality of conventional display areas S1 and a plurality of anti-peep display areas S2. The conventional display areas S1 and the anti-peep display areas S2 are provided to be controlled to be lit up and turned off individually, and all extend in a first direction. The plurality of conventional display areas S1 and the plurality of anti-peep display areas S2 are alternately arranged in a second direction. The first direction intersects with the second direction. As can be seen from the above, the conventional display areas S1 and the anti-peep display areas S2 are effectively separated, so that a light shielding structure 20 shields light from the conventional display areas S1 and the anti-peep display areas S2 respectively, thereby avoiding the influence of the shielding effects of both, and having better display effect.

In some exemplary embodiments, as shown in FIG. 1, a conventional display area S1 may include a plurality of first repeating units 1 sequentially arranged in the first direction, and an anti-peep display area S2 may include a plurality of second repeating units 2 also sequentially arranged in the first direction. The first repeating units 1 in all of the conventional display areas S1 and the second repeating units 2 in all of the anti-peep display areas S2 are arranged together to form an array arrangement. The first direction may be perpendicular to the second direction, a row direction of the array may be consistent with the first direction, and a column direction of the array may be consistent with the second direction. A row of first repeating units 1 and a row of second repeating units 2 are alternately arranged. On a single column, the first repeating units 1 and the second repeating units 2 are alternately arranged. That is, in the second direction, the second repeating units 2 and the first repeating units 1 are provided to be alternately arranged. The conventional display areas S1 and the anti-peep display areas S2 may be controlled to be lit up and turned off individually, so that in the pixel arrangement structure, only the conventional display areas S1 are lit up and turned off, or only the anti-peep display areas S2 are lit up and turned off, or the conventional display areas S1 and the anti-peep display areas S2 are lit up and turned off at the same time. When the conventional display areas S1 and the anti-peep display areas S2 are lit up at the same time, the display device is in a display state; and when only the anti-peep display areas S2 are lit up, the display device is in an anti-peep state.

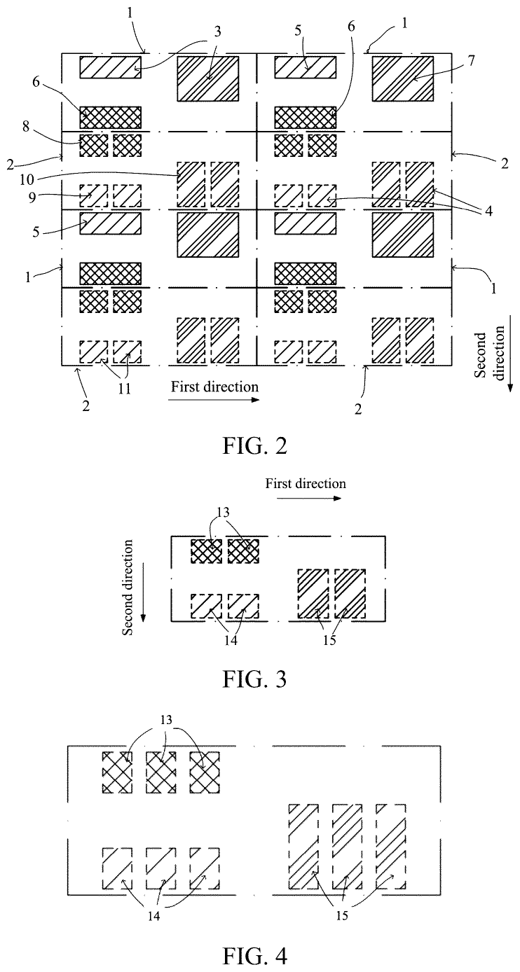

In some exemplary embodiments, as shown in FIG. 2, a first repeating unit 1 may include a plurality of conventional sub-pixels 3, which may be a first conventional sub-pixel 5, a second conventional sub-pixel 6, and a third conventional sub-pixel 7. Each of the first conventional sub-pixel 5, the second conventional sub-pixel 6, and the third conventional sub-pixel 7 has a different color. The first conventional sub-pixel 5 may have a color of green, the second conventional sub-pixel 6 may have a color of red, and the third conventional sub-pixel 7 may have a color of blue. Quantities of the first conventional sub-pixel 5, the second conventional sub-pixel 6 and the third conventional sub-pixel 7 may all be one, but are not limited thereto, as long as the quantities are greater than or equal to one. For example, there may be two first conventional sub-pixels 5, one second conventional sub-pixel 6 and one third conventional sub-pixel 7. For another example, there may be one first conventional sub-pixel 5, one second conventional sub-pixel 6 and two third conventional sub-pixels 7. As also shown in FIG. 2, outer contours of the first conventional sub-pixel 5, the second conventional sub-pixel 6, and the third conventional sub-pixel 7 may all have a rectangular shape, that is, a first rectangle. However, the present disclosure is not limited thereto. The outer contours of the conventional sub-pixels 3 may all have a circular shape, a diamond shape, and the like. Alternatively, the outer contours of part of the conventional sub-pixels 3 may have a rectangular shape, and the outer contours of the other part of the conventional sub-pixels 3 may have other shapes. Outer edges of an outer contour of the first conventional sub-pixel 5, the second conventional sub-pixel 6, and the third conventional sub-pixel 7, that is, outer edges of the first rectangle, include two long sides and two short sides, the long sides may both extend in the first direction, and the short sides may both extend in the second direction. However, the present disclosure is not limited thereto. An extension direction of the long sides may not be the first direction. Lengths of the long sides in the outer contours of the first conventional sub-pixel 5, the second conventional sub-pixel 6, and the third conventional sub-pixel 7 may be the same, lengths of the short sides in the outer contours of the first conventional sub-pixel 5 and the second conventional sub-pixel 6 may be the same, and lengths of the short sides in the outer contour of the third conventional sub-pixel 7 may be larger than the lengths of the short sides in the outer contours of the first conventional sub-pixel 5 and the second conventional sub-pixel 6. However, the present disclosure is not limited thereto. The lengths of the short sides and the long sides of the first conventional sub-pixel 5, the second conventional sub-pixel 6 and the third conventional sub-pixel 7 are not subject to the above limitations. The first conventional sub-pixel 5 and the second conventional sub-pixel 6 may be provided at intervals in the second direction. The third conventional sub-pixel 7 may be provided on a side of the first conventional sub-pixel 5 and the second conventional sub-pixel 6 in the first direction, and a line connecting centers of the first conventional sub-pixel 5, the second conventional sub-pixel 6 and the third conventional sub-pixel 7 forms a triangle. However, the present disclosure is not limited thereto. Positions of the first conventional sub-pixel 5, the second conventional sub-pixel 6 and the third conventional sub-pixel 7 may be randomly changed.

In some exemplary embodiments, as shown in FIGS. 2 and 3, a second repeating unit 2 may include a plurality of anti-peep pixel groups 4, which may be a first anti-peep pixel group 8, a second anti-peep pixel group 9, and a third anti-peep pixel group 10. Each of the first anti-peep pixel group 8, the second anti-peep pixel group 9, and the third anti-peep pixel group 10 may have a different color. The first anti-peep pixel group 8 may have a color of red, the second anti-peep pixel group 9 may have a color of green, and the third anti-peep pixel group 10 may have a color of blue. The second anti-peep pixel group 9 may has a same color as the first conventional sub-pixel 5, the first anti-peep pixel group 8 may has a same color as the second conventional sub-pixel 6, and the third anti-peep pixel group 10 may has a same color as the third conventional sub-pixel 7. However, the present disclosure is not limited thereto. The colors of the first anti-peep pixel group 8, the second anti-peep pixel group 9, and the third anti-peep pixel group 10 may be interchanged with each other. Quantities of the first anti-peep pixel group 8, the second anti-peep pixel group 9 and the third anti-peep pixel group 10 may all be one, but are not limited thereto, as long as the quantities are greater than or equal to one. For example, there may be two first anti-peep pixel groups 8, one second anti-peep pixel group 9 and one third anti-peep pixel group 10. For another example, there may be one first anti-peep pixel group 8, one second anti-peep pixel group 9 and two third anti-peep pixel groups 10. A quantity of the anti-peep pixel groups 4 in the second repeating unit 2 may be the same as a quantity of the conventional sub-pixels 3 in the first repeating unit 1. The quantity of the first anti-peep pixel groups 8 is equal to the quantity of the second conventional sub-pixels 6, the quantity of the second anti-peep pixel groups 9 is equal to the quantity of the first conventional sub-pixels 5, and the quantity of the third anti-peep pixel groups 10 is equal to the quantity of the third conventional sub-pixels 7. However, the present disclosure is not limited thereto. The quantity of the anti-peep pixel groups 4 in the second repeating unit 2 may not be equal to the quantity of the conventional sub-pixels 3 in the first repeating unit 1.

In some exemplary embodiments, as shown in FIGS. 2 and 3, each anti-peep pixel group 4 in at least one second repeating unit 2 may be provided corresponding to conventional sub-pixels 3 of the same color in two first repeating units 1 adjacent to the at least one second repeating unit 2. However, the present disclosure is not limited thereto. The conventional sub-pixels 3 and the anti-peep pixel group 4 of the same color may not correspond to each other. In one second repeating unit 2, one first anti-peep pixel group 8 may be close to the first repeating unit 1 on an upper side, and the first anti-peep pixel group 8 may be correspondingly adjacent to a second conventional sub-pixel 6 of the same color in the first repeating unit 1 on the upper side, that is, the first anti-peep pixel group 8 is provided corresponding to a conventional sub-pixel 3 of the same color in an adjacent first repeating unit 1. One second anti-peep pixel group 9 may be close to the first repeating unit 1 on a lower side, and the second anti-peep pixel group 9 may be correspondingly adjacent to a first conventional sub-pixel 5 of the same color in the first repeating unit 1 on the lower side, that is, the second anti-peep pixel group 9 is provided corresponding to a conventional sub-pixel 3 of the same color in another adjacent first repeating unit 1. A third anti-peep pixel group 10 may be close to the first repeating unit 1 on the lower side, and the third anti-peep pixel group 10 may be correspondingly adjacent to a third conventional sub-pixel 7 of the same color in the first repeating unit 1 on the lower side, that is, the third anti-peep pixel group 10 is provided corresponding to a third conventional sub-pixel 7 of the same color in the adjacent first repeating unit 1. In one first repeating unit 1, a first conventional sub-pixel 5 may be close to a second repeating unit 2 on an upper side, and the first conventional sub-pixel 5 may be correspondingly adjacent to a second anti-peep pixel group 9 of the same color in a second repeating unit 2 on the upper side, that is, the first conventional sub-pixel 5 is provided corresponding to an anti-peep pixel group 4 of the same color in an adjacent second repeating unit 2. A second conventional sub-pixel 6 may be close to a second repeating unit 2 on the lower side, and the second conventional sub-pixel 6 may be correspondingly adjacent to a first anti-peep pixel group 8 of the same color in a second repeating unit 2 on the lower side, that is, the second conventional sub-pixel 6 is provided corresponding to an anti-peep pixel group 4 of the same color in another adjacent second repeating unit 2. A third conventional sub-pixel 7 may be close to the second repeating unit 2 on the upper side, and the third conventional sub-pixel 7 may be correspondingly adjacent to a third anti-peep pixel group 10 of the same color in the second repeating unit 2 on the upper side, that is, the third conventional sub-pixel 7 is provided corresponding to the third anti-peep pixel group 10 of the same color in an adjacent second repeating unit 2. Each of the conventional sub-pixels 3 in each of the first repeating units 1 may find a correspondence with an anti-peep pixel group 4 of the same color in two adjacent first repeating units 1. It can be seen that the conventional sub-pixel 3 is close to the anti-peep pixel group 4 of the same color, which facilitates circuit wiring, simplifies the structure, facilitates production, and reduces production costs.

In some exemplary embodiments, as shown in FIG. 8, positions of the plurality of anti-peep pixel groups 4 in the second repeating units 2 may be randomly arranged. In one second repeating unit 2, a first anti-peep pixel group 8 is close to a first repeating unit 1 on a lower side and is adjacent to a first conventional sub-pixel 5 of a different color, and a second anti-peep pixel group 9 is close to a first repeating unit 1 on an upper side, and is adjacent to a second conventional sub-pixel 6 of a different color. In another second repeating unit 2, a third anti-peep pixel group 10 is close to a first repeating unit 1 on an upper side, and is adjacent to a second conventional sub-pixel 6 of a different color, and a second anti-peep pixel group 9 is close to a first repeating unit 1 on a lower side, and is adjacent to a third conventional sub-pixel 7 of a different color. It can be seen that a conventional sub-pixel 3 and an anti-peep pixel group 4 of the same color are not close in position, or a conventional sub-pixel 3 and an anti-peep pixel groups 4 adjacent to each other may have different colors, or adjacent second repeating unit 2 and first repeating unit 1 may not have a conventional sub-pixel 3 and an anti-peep pixel group 4 provided in corresponding positions, and mutual positions of the respective anti-peep pixel groups 4 are not limited to the positions in FIG. 8, and may be randomly arranged.

In some exemplary embodiments, as shown in FIGS. 2 and 3, at least one anti-peep pixel group 4 may include a plurality of anti-peep sub-pixels 11 provided to be spaced apart. An anti-peep pixel group 4 may include two anti-peep sub-pixels 11, which may be provided at intervals in the first direction. A first anti-peep pixel group 8 may include two first anti-peep sub-pixels 13, a second anti-peep pixel group 9 may include two second anti-peep sub-pixels 14, and a third anti-peep pixel group 10 may include two third anti-peep sub-pixels 15. The two first anti-peep sub-pixels 13 may be provided at intervals in the first direction, the two second anti-peep sub-pixels 14 may be provided at intervals in the first direction, and the two third anti-peep sub-pixels 15 may be provided at intervals in the first direction. The anti-peep pixel group 4 is divided into two portions, so as to guarantee the aperture ratio and prevent the extension length in the first direction from being too long. Positions of the plurality of anti-peep sub-pixels 11 are not limited to being arranged sequentially in the first direction and may be randomly distributed without conventionality. Outer contours of the two anti-peep sub-pixels 11 may be rectangles of the same size, that is, second rectangles. However, the present disclosure is not limited thereto. For example, one of the outer contours of the two anti-peep sub-pixels 11 may be rectangular, and the other of the outer contours of the two anti-peep sub-pixels 11 may be of another shape. For another example, the outer contours of the two anti-peep sub-pixels 11 may both be other shapes. For still another example, the outer contours of the two anti-peep sub-pixels 11 may both be rectangular, but sizes may be different.

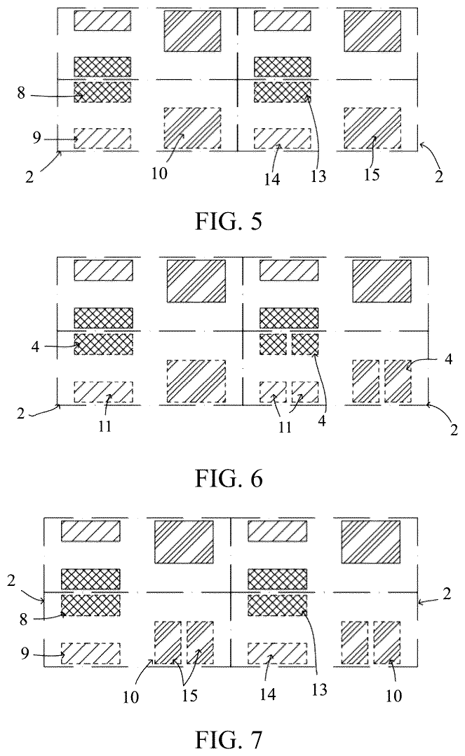

In some exemplary embodiments, as shown in FIG. 5, at least one anti-peep pixel group 4 may be a non-separable anti-peep sub-pixel 11. The first anti-peep pixel group 8 may be a first anti-peep sub-pixel 13, the second anti-peep pixel group 9 may be a second anti-peep sub-pixel 14, and the third anti-peep pixel group 10 may be a third anti-peep sub-pixel 15. The first anti-peep sub-pixel 13, the second anti-peep sub-pixel 14, and the third anti-peep sub-pixel 15 are all rectangular. However, the present disclosure is not limited thereto. For example, the outer contour of the anti-peep sub-pixel 11 may be of other shapes, or part of the anti-peep pixel groups 4 may have a rectangular shape, and the other part of the anti-peep pixel groups 4 may have other shapes.

In some exemplary embodiments, as shown in FIG. 4, an anti-peep pixel group 4 includes three anti-peep sub-pixels 11 provided at intervals in the first direction. The first anti-peep pixel group 8 includes three first anti-peep sub-pixels 13, the second anti-peep pixel group 9 includes three second anti-peep sub-pixels 14, and the third anti-peep pixel group 10 includes three third anti-peep sub-pixels 15. The three first anti-peep sub-pixels 13 are provided at intervals in the first direction, the three second anti-peep sub-pixels 14 are provided at intervals in the first direction, and the three third anti-peep sub-pixels 15 are provided at intervals in the first direction. The anti-peep pixel group 4 is divided into three portions. Positions of the three anti-peep sub-pixels 11 are not limited to being arranged sequentially in the first direction, and may be randomly distributed without conventionality. A quantity of the anti-peep sub-pixels 11 may be three or more. Outer contours of the three anti-peep sub-pixels 11 may be rectangles of a same size. However, the present disclosure is not limited thereto. For example, one of the outer contours of the three anti-peep sub-pixels 11 may be rectangular, and the others of the outer contours of the three anti-peep sub-pixels 11 may be of other shapes. For another example, the outer contours of the three anti-peep sub-pixels 11 may all be of other shapes. For still another example, the outer contours of the three anti-peep sub-pixels 11 may all be rectangular, but sizes may be different.

In some exemplary embodiments, as shown in FIG. 6, each anti-peep pixel group 4 in at least one second repeating unit 2 may include two anti-peep sub-pixels 11, and each anti-peep pixel group 4 in at least one second repeating unit 2 may include one anti-peep sub-pixel 11, forming two types of second repeating units 2, which may be arranged according to a certain rule or randomly. For example, in FIG. 6, in the second repeating unit 2 on the left, the first anti-peep pixel group 8 may be one first anti-peep sub-pixel 13, the second anti-peep pixel group 9 may be one second anti-peep sub-pixel 14, and the third anti-peep pixel group 10 may be one third anti-peep sub-pixel 15. In the second repeating unit 2 on the right, the first anti-peep pixel group 8 includes two first anti-peep sub-pixels 13, the second anti-peep pixel group 9 includes two second anti-peep sub-pixels 14, and the third anti-peep pixel group 10 includes two third anti-peep sub-pixels 15. However, the present disclosure is not limited thereto. This pixel arrangement structure may include multiple types of second repeating units 2, different types of second repeating units 2 are distinguished according to the quantity of anti-peep sub-pixels 11 in the anti-peep pixel group 4, and different types of second repeating units 2 may be arranged according to a certain rule or randomly.

In some exemplary embodiments, as shown in FIG. 7, part of the anti-peep pixel groups 4 in the second repeating unit 2 may include two anti-peep sub-pixels 11 and part of the anti-peep pixel groups 4 may include one anti-peep sub-pixel 11. For example, in the second repeating unit 2, the first anti-peep pixel group 8 may be one first anti-peep sub-pixel 13, the second anti-peep pixel group 9 may be one second anti-peep sub-pixel 14, and the third anti-peep pixel group 10 includes two third anti-peep sub-pixels 15, forming a second repeating unit 2 in which the quantity of anti-peep sub-pixels 11 varies between different anti-peep pixel groups 4. However, the present disclosure is not limited thereto. For example, in one second repeating unit 2, the first anti-peep pixel group 8 may include two first anti-peep sub-pixels 13, the second anti-peep pixel group 9 may be one second anti-peep sub-pixel 14, the third anti-peep pixel group 10 may include two third anti-peep sub-pixels 15, and the quantities of the first anti-peep sub-pixels 13, the second anti-peep sub-pixels 14 and the third anti-peep sub-pixels 15 may not be limited.

In some exemplary embodiments, as shown in FIG. 1, in a shared state, all the anti-peep sub-pixels 11 and all the conventional sub-pixels 3 are lit up to form an S-stripe-like arrangement structure. One conventional display area S1 and an adjacent anti-peep display area S2 may form a single horizontal line display pixel, which refers to a pixel combination formed by a plurality of repeating pixel units arranged in a horizontal and straight line. Triangle T2 is a white dot pixel structure, which refers to a line connecting centers of a plurality of pixels in the repeating units constituting the single horizontal line display pixel. In an anti-peep state, all the anti-peep sub-pixels 11 are lit up, all the conventional sub-pixels 3 are turned off, the anti-peep display area S2 constitutes a single horizontal line display pixel, and triangle T1 is a white dot pixel structure.

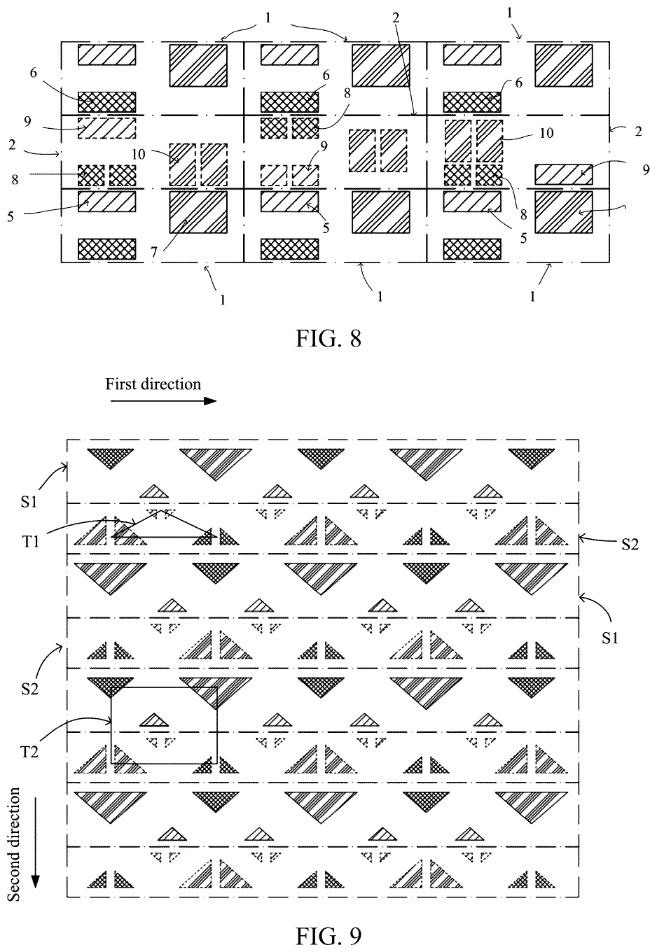

In some exemplary embodiments, as shown in FIGS. 9 to 12, in this pixel arrangement structure, the conventional display area S1 may be divided into first repeating units 1 as shown in FIG. 11, and the anti-peep display area S2 may be divided into second repeating units 2 as shown in FIG. 12. However, the present disclosure is not limited thereto. The first repeating units 1 and the second repeating units 2 may be combined in other manners different from the above combination. A first repeating unit 1 may include a plurality of conventional sub-pixels 3, which may be a first conventional sub-pixel 5, a second conventional sub-pixel 6, and a third conventional sub-pixel 7. Each of the first conventional sub-pixel 5, the second conventional sub-pixel 6, and the third conventional sub-pixel 7 has a different color. The first conventional sub-pixel 5 may have a color of green, the second conventional sub-pixel 6 may have a color of red, and the third conventional sub-pixel 7 may have a color of blue. A quantity of the first conventional sub-pixels 5 may be two, and quantities of the second conventional sub-pixels 6 and the third conventional sub-pixels 7 may both be one, which is not limited thereto, as long as the quantities is greater than or equal to one. As also shown in FIG. 11, outer contour shapes of the first conventional sub-pixels 5, the second conventional sub-pixel 6, and the third conventional sub-pixel 7 may all be triangular, that is, a first triangle. However, the present disclosure is not limited thereto. Outer contour shapes of the conventional sub-pixels 3 may all be circular, diamond, rectangular, and the like, or the outer contour shapes of part of the conventional sub-pixels 3 may be triangular, and the outer contour shapes of the other part of the conventional sub-pixels 3 may be of other shapes. The outer contour shapes of the first conventional sub-pixels 5, the second conventional sub-pixel 6, and the third conventional sub-pixel 7 may all be right triangles. The outer contours of the first conventional sub-pixels 5, the second conventional sub-pixel 6, and the third conventional sub-pixel 7 each include two right-angled sides and a hypotenuse. Hypotenuses in the outer contours of the second conventional sub-pixel 6 and the third conventional sub-pixel 7 may face a side in the second direction, and hypotenuses in outer contours of the two first conventional sub-pixels 5 may both face the other side in the second direction. However, the present disclosure is not limited thereto. Orientations of the hypotenuses in the outer contours of the first conventional sub-pixel 5, the second conventional sub-pixel 6, and the third conventional sub-pixel 7 may be random and unlimited. The two first conventional sub-pixels 5 may have a same size, and the first conventional sub-pixel 5, the second conventional sub-pixel 6, and the third conventional sub-pixel 7 may have different sizes. However, the present disclosure is not limited thereto. For example, two of the first conventional sub-pixel 5, the second conventional sub-pixel 6, and the third conventional sub-pixel 7 have a same size. The two first conventional sub-pixels 5 may be provided at intervals in the first direction, the second conventional sub-pixel 6 and the third conventional sub-pixel 7 may be provided at intervals in the first direction. However, the present disclosure is not limited thereto. Positions of the first conventional sub-pixels 5, the second conventional sub-pixel 6 and the third conventional sub-pixel 7 may be adjusted.

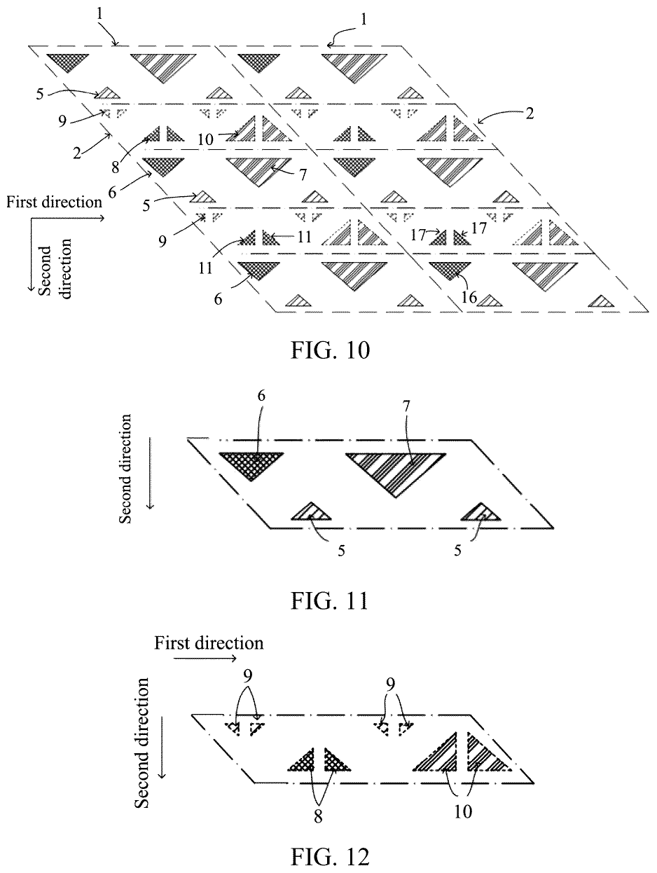

In some exemplary embodiments, as shown in FIGS. 9 to 12, an anti-peep pixel group 4 includes two anti-peep sub-pixels 11 provided at intervals in the first direction. The first anti-peep pixel group 8 includes two first anti-peep sub-pixels 13, the second anti-peep pixel group 9 includes two second anti-peep sub-pixels 14, and the third anti-peep pixel group 10 includes two third anti-peep sub-pixels 15. The two first anti-peep sub-pixels 13 are provided at intervals in the first direction, the two second anti-peep sub-pixels 14 are provided at intervals in the first direction, and the two third anti-peep sub-pixels 15 are provided at intervals in the first direction. The anti-peep pixel group 4 is divided into two portions, so as to guarantee the aperture ratio and prevent the extension length in the first direction from being too long. Positions of the plurality of anti-peep sub-pixels 11 are not limited to being arranged sequentially in the first direction and may be randomly distributed without conventionality. Outer contours of the two anti-peep sub-pixels 11 may be triangles of the same size, that is, two second triangles of the same size. However, the present disclosure is not limited thereto. For example, one of the outer contours of the two anti-peep sub-pixels 11 may be a triangle, and the other of the outer contours of the two anti-peep sub-pixels 11 may be other shapes. For another example, the outer contours of the two anti-peep sub-pixels 11 may both be other shapes. For still another example, the outer contours of the two anti-peep sub-pixels 11 may both be triangles, but sizes may be different. As shown in FIG. 10, hypotenuses in the outer contours of the two anti-peep sub-pixels 11 may be provided facing away from each other, one right-angled side in the outer contour of one anti-peep sub-pixel 11 may face the other anti-peep sub-pixel 11, each of the outer contours of the two anti-peep sub-pixels 11 may have one right-angled side facing an adjacent conventional sub-pixel 3, and the hypotenuse in the outer contour of the conventional sub-pixel 3 faces an adjacent anti-peep pixel group 4.

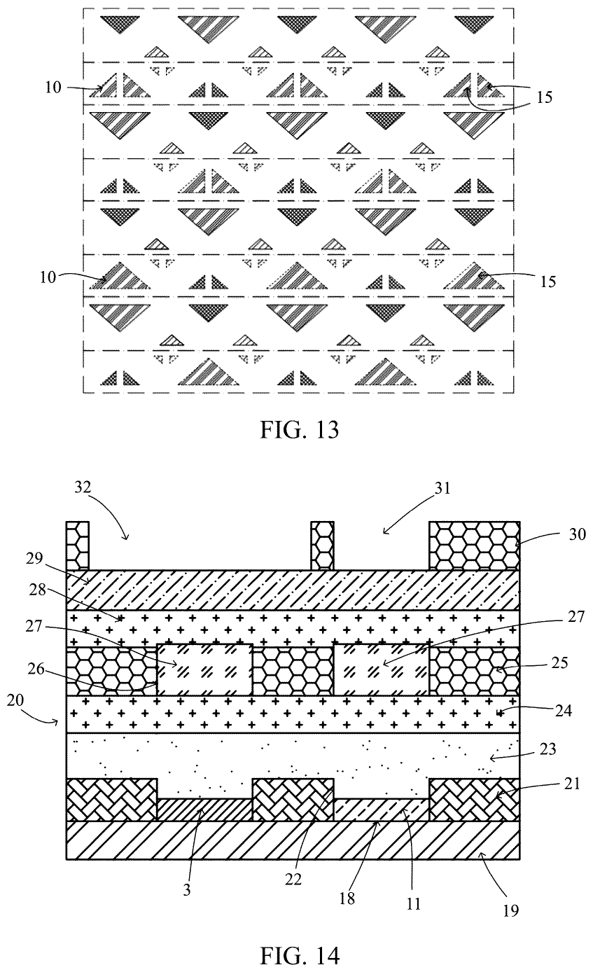

In some exemplary embodiments, as shown in FIG. 13, part of the anti-peep pixel groups 4 includes two anti-peep sub-pixels 11, and the other part of the anti-peep pixel groups 4 may be one non-separable anti-peep sub-pixel 11. For example, part of the third anti-peep pixel groups 10 includes two third anti-peep sub-pixels 15 provided at intervals in the first direction, and the other part of the third anti-peep pixel groups 10 may be one non-separable third anti-peep sub-pixel 15. However, the present disclosure is not limited thereto. For example, one or both of the first anti-peep pixel group 8 and the second anti-peep pixel group 9 have different quantities of anti-peep sub-pixels 11. The quantity of anti-peep sub-pixels 11 in each anti-peep pixel group 4 is not limited to one and two, and may be three or more.

In some exemplary embodiments, as shown in FIG. 9, in a shared state, all the anti-peep sub-pixels 11 and all the conventional sub-pixels 3 are lit up to form a blue diamond-like arrangement structure. A conventional display area S1 and an adjacent anti-peep display area S2 constitute a single horizontal line display pixel, and rectangle T2 is a white dot pixel structure. In an anti-peep state, all the anti-peep sub-pixels 11 are lit up, all the conventional sub-pixels 3 are turned off, the anti-peep display area S2 constitutes a single horizontal line display pixel, and triangle T1 is a white dot pixel structure.

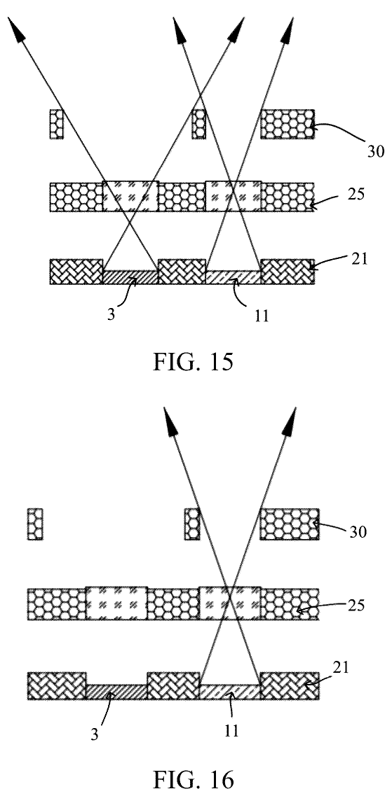

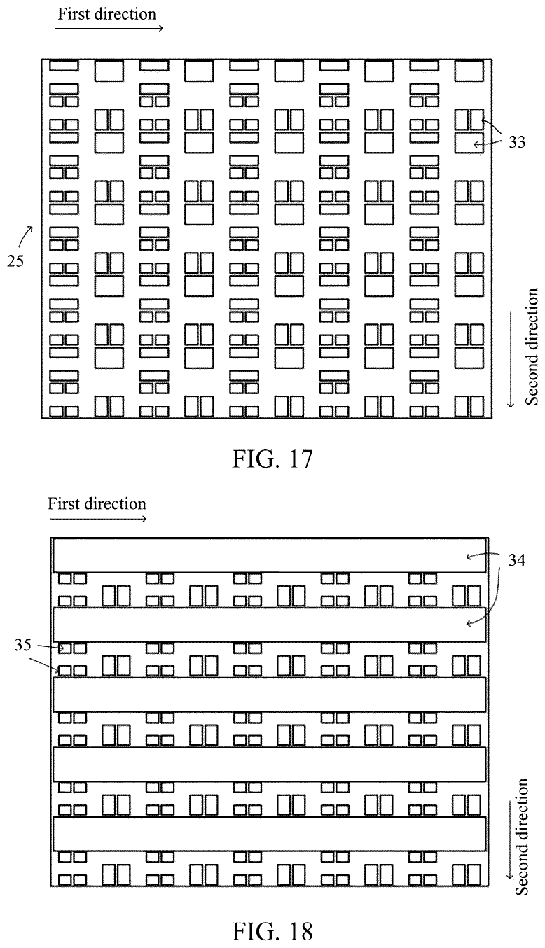

In some exemplary embodiments, as shown in FIGS. 14 to 18, a display panel includes a substrate 19, a pixel definition layer 21 and a light shielding structure 20, and further includes the pixel arrangement structure 18 described above. The pixel definition layer 21 is provided on the substrate 19, and is provided with an opening area 22. The pixel arrangement structure 18 is provided corresponding to the opening area 22. The light shielding structure 20 is provided on a side of the pixel definition layer 21 facing away from the substrate 19. The pixel definition layer 21 may be made of a black material (PDL). The opening area 22 is a plurality of holes penetrating the pixel definition layer 21, and the anti-peep sub-pixels 11 and the conventional sub-pixels 3 are correspondingly arranged in the holes to form the pixel arrangement structure 18. The adjacent anti-peep sub-pixel 11 and conventional sub-pixel 3, two adjacent anti-peep sub-pixels 11 and two adjacent conventional sub-pixels 3 are separated by the PDL. A thin film encapsulation layer (TFE layer) 23 and a first coating (On Cell Touch layer) 24 are provided between the pixel definition layer 21 and the light shielding structure 20. The thin film encapsulation layer (TFE layer) 23 may be in a three-layer such as inorganic/organic/inorganic or a multi-layer structure with a thickness of 8 μm to 20 μm. A Touch layer may be composed of one or more layers of metal grids. In order to reduce stray light, metal traces are blackened below and coated with a coating above. A thickness of the coating may be 2 μm˜5 μm.

In some exemplary embodiments, as shown in FIGS. 14-18, the light shielding structure 20 includes a first black matrix layer 25 and a second black matrix layer 30. The second black matrix layer 30 may be located on a side of the first black matrix layer 25 facing away from the pixel definition layer 21, and a distance between the first black matrix layer 25 and the second black matrix layer 30 is greater than 0. Both the first black matrix layer 25 and the second black matrix layer 30 may be made of a black light shielding material (BM). The first black matrix layer 25 may be provided with a first opening area 26 including a plurality of first openings 33. The quantity and external dimensions of the first openings 33 are provided to match those of the anti-peep sub-pixels 11 and the conventional sub-pixels 3. A filter layer 27 is installed in a first opening 33, and the filter layer 27 is made of a filter material (CF). The second black matrix layer 30 may be provided with a second opening area 31 and a third opening area 32. The second opening area 31 includes a strip-shaped second opening 34 extending in a transverse direction. The third opening area 32 includes a plurality of third openings 35. The second opening 34 is provided corresponding to the conventional display area S1, so that light of the conventional sub-pixel 3 is not blocked by the second black matrix layer 30. The quantity and external dimensions of the plurality of third openings 35 are provided to match those of the anti-peep sub-pixels 11. The second black matrix layer 30 blocks light of the anti-peep sub-pixel 11 to the left and right sides to realize the anti-peep function. A second coating 28 and an organic layer 29 (IJP) may be provided between the first black matrix layer 25 and the second black matrix layer 30. A thickness of the second coating 28 may be 3 μm to 8 μm, a thickness of the organic layer 29 may be 20 μm to 40 μm, and thicknesses of the first black matrix layer 25 and the second black matrix layer 30 may be 3 μm to 5 μm.

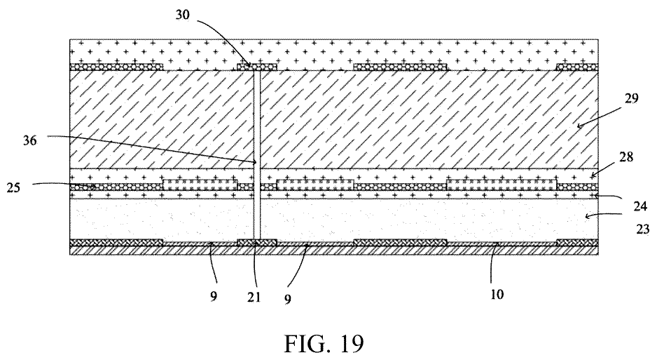

In some exemplary embodiments, as shown in FIG. 19, the display panel includes a light control film 36 in an LCF (Light control film) structure, which may extend from the pixel definition layer 21 to the second black matrix layer 30. The light control film 36 penetrates a structure between the pixel definition layer 21 and the second black matrix layer 30, that is, it penetrates the first black matrix layer 25, the second coating 28, the organic layer 29, the first coating 24, and the like. The light control film 36 may be formed in a multiple coating exposure mode or an etching mode. The light control film 36 may be provided between two adjacent anti-peep sub-pixels 11, that is, there is a light control film 36 between two anti-peep sub-pixels 11 of the same color, which may effectively control light and improve the display effect. For example, there is a light control film 36 between two second anti-peep sub-pixels 9 which are both green. A position of the light control film 36 is not limited to this. For example, the light control film 36 may be provided between part of the anti-peep sub-pixels 11 of the same color, and the light control film 36 may not be provided between the other part of the anti-peep sub-pixels 11 of the same color.

In some exemplary embodiments, a display device is provided, which includes the display panel described above.

The above described embodiments are only illustrative of several embodiments of the present disclosure, and the description thereof is more specific and detailed, but the contents described are only embodiments adopted for the convenience of understanding the present disclosure, and are not intended to limit the present disclosure. Any person skilled in the art to which the present disclosure pertains may make any modification and variation in implementation forms and details without departing from the spirit and scope disclosed in the present disclosure. However, the scope of patent protection of the present disclosure is still subject to the scope defined by the appended claims.

1. A pixel arrangement structure, comprising a plurality of conventional display areas and a plurality of anti-peep display areas, wherein the plurality of conventional display areas and the plurality of anti-peep display areas are provided to be controlled to be lit up and turned off individually, and all extend in a first direction; the plurality of conventional display areas and the plurality of anti-peep display areas are alternately arranged in a second direction; and the first direction intersects with the second direction.

2. The pixel arrangement structure according to claim 1, wherein a conventional display area comprises a plurality of first repeating units sequentially arranged in the first direction, and an anti-peep display area comprises a plurality of second repeating units sequentially arranged in the first direction; and
the first repeating units in the plurality of conventional display areas and the second repeating units in the plurality of anti-peep display areas are arranged in an array.

3. The pixel arrangement structure according to claim 2, wherein the second repeating units and the first repeating units are arranged alternately in the second direction;
a first repeating unit comprises a plurality of conventional sub-pixels, and a second repeating unit comprises a plurality of anti-peep pixel groups; and
in adjacent first repeating unit and second repeating unit, at least one of the conventional sub-pixels in the first repeating unit is provided corresponding to at least one of the anti-peep pixel groups in the second repeating unit and has a same color as at least one of the anti-peep pixel groups in the second repeating unit.

4. The pixel arrangement structure according to claim 3, wherein part of the conventional sub-pixels in the first repeating unit is provided corresponding to part of the anti-peep pixel groups in an adjacent second repeating unit and has a same color as part of the anti-peep pixel groups in an adjacent second repeating unit, and the other part of the conventional sub-pixels is provided corresponding to part of the anti-peep pixel groups in another second repeating unit and has a same color as part of the anti-peep pixel groups in another second repeating unit.

5. The pixel arrangement structure according to claim 3, wherein the plurality of conventional sub-pixels comprise a first conventional sub-pixel, a second conventional sub-pixel, and a third conventional sub-pixel, and the plurality of anti-peep pixel groups comprise a first anti-peep pixel group, a second anti-peep pixel group, and a third anti-peep pixel group; and
the first anti-peep pixel group is provided to be consistent in color with the second conventional sub-pixel, the second anti-peep pixel group is provided to be consistent in color with the first conventional sub-pixel, and the third anti-peep pixel group is provided to be consistent in color with the third conventional sub-pixel.

6. The pixel arrangement structure according to claim 3, wherein at least one of the anti-peep pixel groups comprises a plurality of anti-peep sub-pixels provided at pairwise intervals.

7. The pixel arrangement structure according to claim 6, wherein at least one of the anti-peep pixel groups comprises two anti-peep sub-pixels provided at intervals in the first direction.

8. The pixel arrangement structure according to claim 7, wherein an outer contour of at least one of the conventional sub-pixels is provided as a first rectangle, long sides of the first rectangle extend in the first direction, and outer contours of two of the anti-peep sub-pixels are provided as identical second rectangles.

9. The pixel arrangement structure according to claim 7, wherein an outer contour of at least one of the conventional sub-pixels is provided as a first triangle, and outer contours of two of the anti-peep sub-pixels are provided as two second triangles of the same size.

10. The pixel arrangement structure according to claim 9, wherein all the first triangle and the second triangles are provided as right triangles, and a hypotenuse of the first triangle is provided to face an adjacent anti-peep pixel group; and
hypotenuses of the two second triangles are provided facing away from each other, and a right-angled side of a second triangle is provided to face an adjacent conventional sub-pixel.

11. A display panel, comprising a substrate, a pixel definition layer and a light shielding structure, and further comprising the pixel arrangement structure according to claim 1, wherein the pixel definition layer is provided on the substrate, and is provided with an opening area; the pixel arrangement structure is provided corresponding to the opening area; and the light shielding structure is provided on a side of the pixel definition layer facing away from the substrate.

12. A display panel, comprising a substrate, a pixel definition layer, a light shielding structure and a light control film, and further comprising the pixel arrangement structure according to claim 6, wherein the pixel definition layer is provided on the substrate, and is provided with an opening area; the pixel arrangement structure is provided corresponding to the opening area; and the light shielding structure is located on a side of the pixel definition layer facing away from the substrate; and
the light control film is provided to extend from the pixel definition layer to a side of the light shielding structure facing away from the pixel definition layer.

13. The display panel according to claim 12, wherein the light shielding structure comprises a first black matrix layer spaced apart from the pixel definition layer and a second black matrix layer provided on a side of the first black matrix layer facing away from the pixel definition layer, wherein a distance between the first black matrix layer and the second black matrix layer is greater than 0; and
the light control film is provided to extend from the pixel definition layer to the second black matrix layer, and the light control film is provided between two adjacent anti-peep sub-pixels.

14. A display device, comprising the display panel according to claim 11.

15. The pixel arrangement structure according to claim 4, wherein at least one of the anti-peep pixel groups comprises a plurality of anti-peep sub-pixels provided at pairwise intervals.

16. The pixel arrangement structure according to claim 5, wherein at least one of the anti-peep pixel groups comprises a plurality of anti-peep sub-pixels provided at pairwise intervals.

17. A display panel, comprising a substrate, a pixel definition layer and a light shielding structure, and further comprising the pixel arrangement structure according to claim 2, wherein the pixel definition layer is provided on the substrate, and is provided with an opening area; the pixel arrangement structure is provided corresponding to the opening area; and the light shielding structure is provided on a side of the pixel definition layer facing away from the substrate.

18. A display panel, comprising a substrate, a pixel definition layer and a light shielding structure, and further comprising the pixel arrangement structure according to claim 3, wherein the pixel definition layer is provided on the substrate, and is provided with an opening area; the pixel arrangement structure is provided corresponding to the opening area; and the light shielding structure is provided on a side of the pixel definition layer facing away from the substrate.

19. A display panel, comprising a substrate, a pixel definition layer, a light shielding structure and a light control film, and further comprising the pixel arrangement structure according to claim 7, wherein the pixel definition layer is provided on the substrate, and is provided with an opening area; the pixel arrangement structure is provided corresponding to the opening area; and the light shielding structure is located on a side of the pixel definition layer facing away from the substrate; and
the light control film is provided to extend from the pixel definition layer to a side of the light shielding structure facing away from the pixel definition layer.

20. A display panel, comprising a substrate, a pixel definition layer, a light shielding structure and a light control film, and further comprising the pixel arrangement structure according to claim 8, wherein the pixel definition layer is provided on the substrate, and is provided with an opening area; the pixel arrangement structure is provided corresponding to the opening area; and the light shielding structure is located on a side of the pixel definition layer facing away from the substrate; and
the light control film is provided to extend from the pixel definition layer to a side of the light shielding structure facing away from the pixel definition layer.
